(19) United States
(12) Patent Application Publication
(10) Pub. No.: US 2025/0251435 A1
(43) Pub. Date: Aug. 7, 2025

(54) INTERFEROMETRIC INTERFERENCE EXCISION IN RYDBERG RECEIVERS

(71) Applicant: BAE SYSTEMS Information and Electronic Systems Integration Inc., Nashua, NH (US)

(72) Inventor: Alec Yonika, Somerset, MA (US)

(73) Assignee: BAE SYSTEMS Information and Electronic Systems Integration Inc., Nashua, NH (US)

(21) Appl. No.: 18/432,476

(22) Filed: Feb. 5, 2024

(51) Int. Cl. G01R 29/08; G02B 27/14

(52) U.S. Cl. CPC G01R 29/0885; G01R 29/0892; G02B 27/144

(57) ABSTRACT

A receiver includes a first vapor cell and a second vapor cell, wherein the first vapor cell is exposed to a signal of interest and an interfering signal, and wherein the second vapor cell is exposed to at least the interfering signal. In an example, the first and second vapor cells includes an atomic medium including Rydberg atoms. The receiver includes an optical arrangement configured to (i) transmit a first probe laser beam to the first vapor cell, and (ii) transmit a second probe laser beam to the second vapor cell; an interferometer configured to (i) process a first laser beam from the first vapor cell, and a second laser beam from the second vapor cell, and (ii) generate a plurality of voltage signals; and a circuit configured to process the plurality of voltage signals and generate an output signal indicative of the signal of interest.

### STATEMENT OF GOVERNMENT INTEREST

This invention was made with United States Government assistance under Contract No. HR001121C0139. The United States Government has certain rights in this invention.

### BACKGROUND

Quantum-based Rydberg radio frequency (RF) receivers are an emerging technology and have seen great advances in the past few years. A Rydberg receiver is capable of sensing an electric field through the use of a vapor cell including vaporized Rydberg atoms optically excited to a relatively high principal quantum number. This excitation induces a large electric dipole moment on the atoms, making them highly susceptible to changes induced by external RF fields. These changes induced by the RF fields can in turn be detected. In more detail, when an atomic medium including excited Rydberg atoms is exposed to an RF signal, an optical transparency of the atomic medium changes based on the applied RF signal. This phenomenon is known as electromagnetically induced transparency (EIT), and such change in transparency can be detected using a laser beam. The laser beam passing through the atomic medium including the Rydberg atoms, with the atomic medium being exposed to the RF signal, can be analyzed, to estimate the applied RF signal. Thus, a time varying RF signal can be detected via its influence on the laser transmission. There remain a number of nontrivial issues with designing and operating a Rydberg RF receiver.

### BRIEF DESCRIPTION OF THE DRAWINGS

FIG. 1 schematically illustrate an electromagnetic wave receiver system configured to receive electromagnetic waves, wherein the receiver uses Rydberg atoms for electromagnetic wave detection, and wherein the receiver is configured to cancel or at least reduce effects of an interfering signal while detecting a signal of interest (SOI), in accordance with an embodiment of the present disclosure.

FIG. 2 illustrates the electromagnetic wave receiver system of FIG. 1, and further illustrates reflection and transmission coefficients of various beam splitters of the electromagnetic wave receiver system, in accordance with an embodiment of the present disclosure.

FIG. 3 illustrates a local oscillator coupled to an example vapor cell of the electromagnetic wave receiver system of FIGS. 1 and 2, in accordance with an embodiment of the present disclosure.

FIGS. 4A, 4B, and 4C, in combination, illustrate a flowchart depicting a method of operating the electromagnetic wave receiver system of FIGS. 1-3, in accordance with an embodiment of the present disclosure.

Although the following detailed description will proceed with reference being made to illustrative examples, many alternatives, modifications, and variations thereof will be apparent in light of this disclosure.

### DETAILED DESCRIPTION

An RF receiver employing Rydberg atoms is disclosed. In an example, the receiver employs a plurality of vapor cells, an interferometer, and an electrical processing circuit. The interferometer and accompanying electrical circuitry are configured to cancel or at least reduce effects of an interfering signal on an output signal of the receiver, such that the output signal is solely or at least primarily indicative of a signal of interest (SOI). In one such embodiment, the receiver includes a first vapor cell and a second vapor cell, each comprising an atomic medium including Rydberg atoms. A first probe signal and a second probe signal are provided to the first and second vapor cells, respectively. The first vapor cell outputs a first laser beam indicative of both the SOI and the interfering signal, and the second vapor cell outputs a second laser beam indicative primarily of the interfering signal. In one such embodiment, the first and second laser signals are processed by a plurality of optical and electro-optical components, which generate a plurality of output laser beams. In an example, the plurality of optical and electro-optical components includes multiple beam splitters, a beam combiner, and an electro-optical modulator (EOM) configured to cause a phase shift (such as a phase reversal) of a laser beam. The output laser beams are each provided to a corresponding photo detector, which in turn generates a corresponding voltage signal. The voltage signals are processed by an electrical processing circuit, which is configured to cancel or at least reduce contributions of the interfering signal and generate an output signal that is indicative of the SOI. Numerous configurations and variations will be apparent in light of this disclosure.

### General Overview

As mentioned herein above, there remain a number of nontrivial issues with designing and operating an RF receiver employing Rydberg atoms. For example, a Rydberg receiver comprises a vapor cell comprising Rydberg atoms. The vapor cell is excited with a probe laser and pump laser, and exposed to an RF signal of interest (SOI). An EIT laser beam that is output by the vapor cell is indicative of the SOI. The resultant EIT laser beam is received as an optical heterodyne induced through mixing of the SOI and a secondary local oscillator (LO). In the presence of interference, additional mixing terms between the interfering signal and the LO and/or SOI produces non-linear signal contributions. This makes it challenging to estimate the SOI from the laser beam output by the vapor cell.

Accordingly, techniques are described herein for an RF receiver employing Rydberg atoms, where the receiver is able to cancel or at least reduce effects of an interfering signal on an output signal of the receiver, such that the output signal is solely or at least primarily indicative of the signal of interest. In one embodiment, the receiver comprises a first vapor cell and a second vapor cell, each comprising an atomic medium including Rydberg atoms. The first vapor cell is tuned to be more sensitive to the SOI and the interfering signal, and the second vapor cell is tuned to be more sensitive to the interfering signal. In response to corresponding probe signal inputs, the first vapor cell outputs a first laser beam indicative of both the SOI and the interfering signal, and the second vapor cell outputs a second laser beam indicative primarily of the interfering signal. The first laser beam is split by a first beam splitter into a first output laser beam and a first intermediate laser beam, and the second laser beam is split by a second beam splitter into a second output laser beam and a second intermediate laser beam. The second intermediate laser beam is phase-shifted by 180° and then combined with the first intermediate laser beam to generate a third output laser beam. The first, second, and third output laser beams are received by first, second, and third photodetectors, respectively, which respectively generate first, second, and third voltage signals. A summation circuit sums the first and third voltage signals to generate a summed signal, and a difference circuit differences the summed signal and the second voltage signal to generate an output signal that is indicative of the SOI, with any effect of the interfering signal largely eliminated or otherwise reduced. Numerous configurations and variations will be apparent in light of this disclosure.

### Architecture

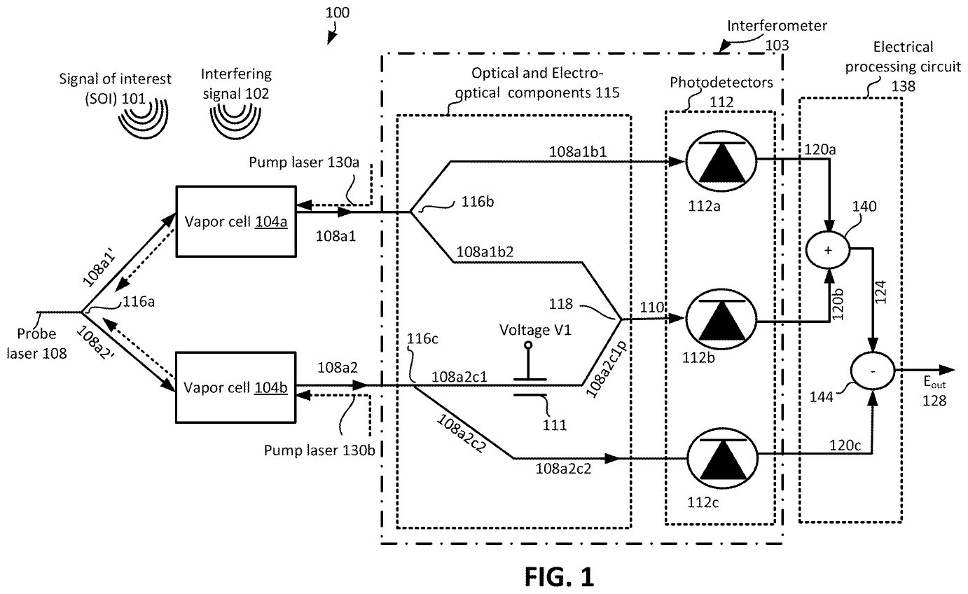

FIG. 1 schematically illustrate an electromagnetic wave receiver system 100 (also referred to herein as receiver 100) configured to receive electromagnetic waves, wherein the receiver 100 uses Rydberg atoms for electromagnetic wave detection, and wherein the receiver 100 is configured to cancel or at least reduce effects of an interfering signal 102 while detecting a signal of interest (SOI) 101, in accordance with an embodiment of the present disclosure.

As illustrated in FIG. 1, the receiver 100 is exposed to a signal of interest (SOI) 101 and an interfering signal 102. The SOI 101 and the interfering signal 102 are generated by corresponding signal generation sources. The SOI 101 and the interfering signal 102 can be any signal having any frequency that can be detected by the receiver. In one advantageous embodiment, each of the SOI 101 and the interfering signal 102 comprises RF signals.

In an example, the receiver 100 comprises a first vapor cell 104a and a second vapor cell 104b, and one or both the vapor cells 104a, 104b are exposed to the SOI 101 and the interfering signal 102. In one example and as describe in detail below, the vapor cell 104a is configured to be relatively more sensitive and responsive to both the SOI 101 and the interfering signal 102, e.g., compared to the vapor cell 104b. On the other hand, the vapor cell 104b is configured to be relatively less sensitive to the SOI 101, such that the SOI 101 lies below the dynamic range, and the vapor cell 104b responds primarily to the interfering signal 102, e.g., compared to the vapor cell 104b. Thus, in an example, the vapor cell 104a is exposed to both the SOI 101 and the interfering signal 102, and the vapor cell 104b is exposed to at least the interfering signal 102 and may also be exposed to the SOI 101. Because of the close locational proximity between the two vapor cells 104a, 104b, in an example, both vapor cells 104a, 104b are exposed to both the SOI 101 and the interfering signal 102.

In an example, each of the vapor cells 104 is a container that is transparent to RF signals, such as the SOI 101 and the interfering signal 102. For example, the SOI 101 and the interfering signal 102 can enter the vapor cell 104, and interact with the contents of the vapor cell 104. In an example, the sidewalls of the vapor cell 104 comprises a glass or a dielectric material that doesn't significantly inhibit or restrict flow of the SOI 101 and the interfering signal 102 through the sidewalls.

In one embodiment, the vapor cells 104 includes an atomic medium comprising vapor of Rydberg atoms. A Rydberg atom is an excited atom comprising one or more electrons having a relatively a high principal quantum number “n”. In an example and on an average, if the quantum number n is higher, the farther the electron is from a nucleus of the atom. Rydberg atoms have an exaggerated response to electric and magnetic fields (e.g., compared to other types of atoms), relatively long decay periods, and electron wavefunctions that approximate (e.g., under some conditions) classical orbits of electrons about a nuclei.

Any appropriate type of Rydberg atoms may be used within the vapor cells 104, such as a low density vapor of alkali atoms (e.g., rubidium-85 atoms), or cesium, or another type of Rydberg atom. Each atom within a vapor cell 104 has a plurality of electron states, including a ground state and a plurality of excited states, such as, for example, at least a higher excited state and a lower excited state (although the atom may have many other excited states). The higher excited state has a higher energy level than the lower excited state.

In a vapor cell 104, an outer electron of an atom may be excited from the ground state to an excited state (such as the higher excited state), e.g., by absorbing a photon. In an example, the electron then decays from the higher excited state to the lower excited state, or maybe even to the ground state. However, in an example, one or more of these transitions may not be allowed, as they are dipole forbidden, e.g., based on a type of Rydberg atoms used.

In the receiver 100, each vapor cell 104 is exposed to a probe laser 108. For example, an incoming or input probe laser 108 is split in two probe lasers 108a1′ and 108a2′, e.g., using an optical arrangement such as a beam splitter 116a. For example, the beam splitter 116a receives the probe laser 108 from a single source, and splits the probe laser 108 in two probe lasers 108a1′ and 108a2′. A beam splitter, such as the beam splitter 116a, is an optical device that splits a beam of light into a transmitted beam and a reflected beam. The beam splitter 116a is also referred to as a junction for the probe laser 108, as at this junction the probe laser 108 is split in the two probe lasers 108a1′ and 108a2′.

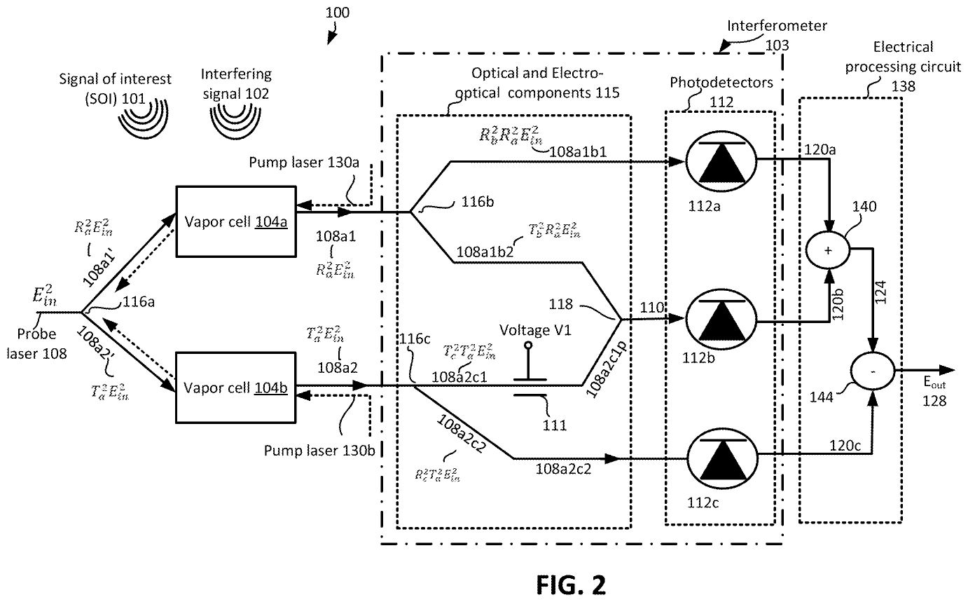

Merely as an example, it is assumed that the probe laser 108a1′ is a reflected component of the probe layer 108, and the probe laser 108a2′ is a transmitted component of the probe laser 108, as described in further detail below with respect to FIG. 2. Note that the splitting of the light beam in a beam splitter can be performed in any preconfigured energy ratio of the transmitted beam and the reflected beam. For example, if a reflection coefficient of a beam splitter is R and a transmission coefficient of the beam splitter is T, then for a lossless beam splitter R²=1−T². The beam splitter 116a can be configured to achieve an appropriate value of R, and a corresponding value of T, based on the above relationship between R and T. The reflection and transmission coefficients of the beam splitter 116a are referred specifically as Rₐ and Tₐ, respectively.

As illustrated in FIG. 1, the probe laser 108a1′ is passed through the atomic medium of the vapor cell 104a, and the probe laser 108a2′ is passed through the atomic medium of the vapor cell 104b. In an example, the probe lasers 108a1′ and 108a2′ have corresponding energies for elevating the Rydberg atoms of the corresponding vapor cells to corresponding excited states.

Another laser, referred to as pump laser or coupling laser 130 are also passed through each vapor cell, e.g., in a direction that is opposite to a direction of the corresponding probe laser, where the pump lasers are illustrated using dashed lines. For example, pump laser 130a is passed through the vapor cell 104a in a direction opposite to a direction of the probe laser 108a1′, and pump laser 130b is passed through the vapor cell 104b in a direction opposite to a direction of the probe laser 108a2′. Note that a path of the probe laser 108a1′ and the pump laser 130a into, through, and out of the vapor cell 104a are the same and in opposite directions. Accordingly, the solid line showing the path of the probe laser 108a1′ and the dashed line showing the path of the pump laser 108a1 into, through, and out of the vapor cell 104a substantially coincide (although they are shown to not coincide for purposes of illustrative clarity in FIG. 1). Similar description applies for the path of the probe laser 108a2′ and the pump laser 130b.

The vapor cell 104a receives the probe laser 108a1′ and the pump laser 130a, and outputs a laser beam 108a1. In an example, the probe laser 108a1′ is modulated by the vapor cell 104a, and the modulated probe laser 108a1′ is output as the laser beam 108a1. Similarly, the vapor cell 104b receives the probe laser 108a2′ and the pump laser 130b, and outputs a laser beam 108a2. As described below, each of the laser beams 108a1 and 108a2 is indicative of the SOI 101 and/or the interfering signal 102.

Referring to the vapor cell 104a, in an example, the probe laser 108a1′ has corresponding energies for elevating the Rydberg atoms of the vapor cell 104a to an excited state. For example, the probe laser 108a1′ is passed through the atomic medium of the vapor cell 104a at a first wavelength, e.g., which corresponds to the energy required to elevate the atom's (such as Rubidium-85 atom's) outer electron from its ground state to a first excited state. The pump laser 130a is also passed through the atomic medium of the vapor cell 104a in the opposite direction, as described above. In an example, the pump laser 130a has relatively higher power level, e.g., compared to the probe laser 108a1′. The pump laser 130a has a second wavelength, e.g., which corresponds to the energy required to elevate the atom's outer electron from the first excited state to a Rydberg state. In an example, a transition from the Rydberg state to the ground state may be forbidden or disallowed, so that a number of atoms at the ground state decreases. Accordingly, the atomic medium becomes more transparent to the probe laser 108a1′, such that there is an increase in transmission of the probe laser 108a1′, which is eventually observable at one or more optical detector 112a, 112b, 112c described below. This phenomenon is known as Electromagnetically Induced Transparency (EIT), and the received signal is known as the EIT signal 108a1. Thus, a laser signal 108a1 output by the vapor cell is an EIT signal. In an example, once the atomic medium of the vapor cell 104a has become transparent to the probe laser 108a1′, another physical effect is exploited to detect the RF electric fields. As the Rydberg atom's outer electron is much further away from the atomic nucleus when in the Rydberg state compared to the ground state, a relatively large dipole moment is generated, which becomes responsive to incident RF electric fields. For example, an incident electric field (such as an RF electrical field) from the SOI 101 and/or the interfering signal 102 may cause a further transition of an electron from the Rydberg state to an adjacent Rydberg state. If the transition from the adjacent Rydberg state to the ground state is not forbidden, then electrons may subsequently drop to the ground state so that the atomic medium becomes less transparent to the probe laser, causing a drop in amplitude of the EIT signal. In an example, a decrease in amplitude of the EIT signal 108a1 is based on (such as proportional to) the amplitude of the incident electric field from the SOI 101 and/or the interfering signal 102. Thus, the amplitude of the laser signal 108a1 is indicative of an amplitude of the electrical field (such as an RF electrical field) within the vapor cell 104a. Thus, by measuring the amplitude of the laser signal 108a1, it is possible to estimate the electrical field within the vapor cell 104a, such as the electrical field generated by the SOI 101 and/or the interfering signal 102. Similarly, by measuring the amplitude of the laser signal 108a2, it is possible to estimate the electrical field (such as an RF electrical field) within the vapor cell 104b.

In one embodiment, the vapor cell 104a is configured to be relatively more sensitive (used for resonant detection) and responsive to both the SOI 101 and the interfering signal 102, e.g., compared to the vapor cell 104b. For example, the RF receiver comprising the vapor cell 104a may be used for resonant detection of both the SOI 101 and the interfering signal 102. In an example, such tuning may be performed by tuning the atomic medium within the vapor cell 104a, by controlling a strength of the pump laser 130a, and/or by controlling a strength of the probe laser 108a1′ (which may be performed by tuning the probe laser 108).

In one embodiment, the vapor cell 104b is configured to be relatively less sensitive (e.g., off-resonant detection) to the SOI 101, such that the SOI 101 lies below the dynamic range, and the vapor cell 104b responds mainly to the interfering signal 102, e.g., compared to the vapor cell 104b.

As described above, the vapor cell 104a is configured to be relatively more sensitive and responsive to both the SOI 101 and the interfering signal 102, e.g., compared to the vapor cell 104b, whereas the vapor cell 104b is configured to be relatively less sensitive (e.g., off-resonant detection) to the SOI 101. Such configurations of the vapor cells 104a and 104b may be achieved by appropriately tuning the vapor cells 104a and 104b. For example, each vapor cell may be tuned to be relatively responsive to a certain frequency or frequency band. In one such example, the tuning of a vapor cell may be accomplished by altering the energy level shift for the electron shell transition within the vapor cell. In another example, the vapor cells may be configured using responsivity tuning, which is the resonant or off-resonant detection capability, and which may be achieved using Autler-Townes splitting for resonant or the AC Stark effect for off-resonant. In this example, the Autler-Townes is a special case of AC Stark.

In an example, to tune the vapor cells 104a, 104b, prior knowledge of the interfering signal 102 may not be needed. For example, the system 100 may be aware a priori of the SOI 101 that is to be detected, and may also be aware of the approximate frequency (e.g., usually a range of frequencies around a center value) that the SOI 101 is to be communicated in. In the case that interfering signal 102 may be present, placing a receiver that is detecting within an adjacent frequency band would allow the interferometric signal excision to function if the interfering signal 102 happens to exist within that band.

In one embodiment, the receiver 100 comprises an interferometer 103 including (i) one or more optical and electro-optical components 115 (also referred to as components 115), and (ii) a plurality of photodetectors 112 (such as photodetectors 112a, 112b, 112c). As illustrated in FIG. 1, the one or more optical and electro-optical components 115 comprises beam splitters 116b, 116c, beam combiner 118, and an electro-optical modulator (EOM) 111.

The one or more optical and electro-optical components 115 receive and process the laser beams 108a1 and 108a2 from the vapor cells 104a, 104b, respectively, and generate output laser beams 108a1b1, 110, and 108a2c2. The photodetectors 112 receive the output laser beams 108a1b1, 110, and 108a2c2, respectively, and generate corresponding voltage signals 120a, 120b, 120c, as illustrated in FIG. 1. An electrical processing circuit 138 subsequently processes the voltage signals 120a, 120b, 120c, to generate an output signal Eₒᵤₜ 128, where the output signal Eₒᵤₜ 128 is indicative of the SOI 101. For example, effects of the interfering signal 102 is eliminated or at least reduced in the output signal Eₒᵤₜ 128, such that the output signal Eₒᵤₜ 128 is indicative only of, or at least primarily of, the SOI 101. Thus, the interferometer 103 and the electrical processing circuit 138 are able to eliminate, or at least reduce, effects of the interfering signal 102 in the output signal Eₒᵤₜ 128. The output signal Eₒᵤₜ 128 is subsequently processed to estimate the SOI 101.

Referring to the components 115, in an example, the laser beam 108a1 output by the vapor cell 104a is split by the beam splitter 116b into laser beams 108a1b1 and 108a1b2. The laser beam 108a1b1 is also referred to as an output laser beam, and is received by the photo detector 112a.

In one embodiment, the laser beam 108a2 output by the vapor cell 104b is split by the beam splitter 116c into laser beams 108a2c1 and 108a2c2. The laser beam 108a2c2 is also referred to as another output laser beam, and is received by the photo detector 112c.

The laser beam 108a2c1 is passed through an electro-optical modulator (EOM) 111 tuned to provide a phase shift to the laser beam 108a2c1, to generate a laser beam 108a2c1p (where the letter “p” at the end signifies that the beam has been phase shifted). Thus, the laser beam 108a2c1p is a phase shifted version of the laser beam 108a2c1. In an example, the EOM 111 provides a phase shift of substantially 180° (e.g., with a tolerance of at most 5°, or 3°, or 2°, or 1°), to generate the laser beam 108a2c1p. In an example, a phase shift provided by the EOM 111 can be controlled by a voltage V1 applied to the EOM 111.

The laser beams 108a1b2 and 108a2c1p are combined in a beam combiner 118, to generate a laser beam 110. The laser beam 110 is also referred to as yet another output laser beam, and is received by the photo detector 112b.

Thus, the photo detector 112a receives output laser beam 108a1b1 that is contributed solely by the vapor cell 104a, and the photo detector 112c receives output laser beam 108a2c2 that is contributed solely from the vapor cell 104b. The photo detector 112b receives output laser beam 110, which has components from both the vapor cells 104a, 104b, such as a linear combination of laser beams from both the vapor cells 104a, 104b.

In an example, a length of various paths the various laser beams traverses (e.g., from a vapor cell to a corresponding photo detector) may be tightly controlled. For example, a path length between the vapor cell 104a, through the beam splitter 116b, to the photo detector 112a is La. Similarly, a path length between the vapor cell 104b, though the beam splitter 116c, to the photo detector 112c is Lc. Also, assume that the path between the vapor cell 104a and the photo detector 112b, though the beam splitter 116b and the beam combiner 118, is Lb; and also the path between the vapor cell 104b and the photo detector 112b, though the beam splitter 116c, the EOM 111, and the beam combiner 118, is also Lb. In an example, La, Lb, and Lc are substantially equal, e.g., within a tolerance margin of at most 5%, or at most 3%, or at most 1%. In an example, effects of any mismatch in the lengths can be reduced or eliminated by tuning the EOM 111, and/or by tuning one or more other EOMs in one or more other paths of the interferometer 103. For example, such additional EOM(s) can be placed strategically in one or more paths of the various laser beams between a vapor cell and a photo detector, and the phase delay may be fine tuned to account for any mismatch in path length(s).

FIG. 2 illustrates the electromagnetic wave receiver system 100 of FIG. 1, and further illustrates reflection and transmission coefficients of various beam splitters 116a, 116b, 116c of the electromagnetic wave receiver system 100, in accordance with an embodiment of the present disclosure. Furthermore, energy of various laser beams is also labelled in FIG. 2.

For example, referring to FIG. 2, an energy of the probe laser 108 is Eᵢₙ². The beam splitter 116a has a reflection coefficient Rₐ, and a transmission coefficient Tₐ. As described above, in an example, it is assumed that the probe laser 108a1′ is the reflected component of the probe laser 108, and the probe laser 108a2′ is the transmitted component of the probe laser 108, although the reverse may also be possible in another example. Accordingly, the probe laser 108a1′ has an energy of Rₐ²Eᵢₙ², and the probe laser 108a2′ has an energy of Tₐ²Eᵢₙ², as labelled in FIG. 2.

The probe laser 108a1′ enters the vapor cell 104a, and an output of the vapor cell 104a is laser beam 108a1 that is indicative of the electrical field that the vapor cell 104a is exposed to and tuned to. Similarly, the probe laser 108a2′ enters the vapor cell 104b, and an output of the vapor cell 104b is laser beam 108a2 that is indicative of the electrical field that the vapor cell 104b is exposed to and tuned to. The energy of the laser beams 108a1 and 108a2 are also of Rₐ²Eᵢₙ² and Tₐ²Eᵢₙ², respectively.

The beam splitter 116b receives the laser beam 108a1 having energy of Rₐ²Eᵢₙ², and has a reflection coefficient R_{b}, and a transmission coefficient T_{b}. Tn an example, it is assumed that the laser beam 108a1b1 is the reflected component of the laser beam 108a1, and the laser beam 108a1b2 is the transmitted component of the laser beam 108a1, although the reverse may also be possible in another example. Accordingly, the laser beam 108a1b1 has an energy of R_{b}²Rₐ²Eᵢₙ², and the laser beam 108a1b2 has an energy of T_{b}²Rₐ²Eᵢₙ², as illustrated in FIG. 2.

The beam splitter 116c receives the laser beam 108a2 having energy of Tₐ²Eᵢₙ², and has a reflection coefficient R_{c}, and a transmission coefficient T_{c}. Tn an example, it is assumed that the laser beam 108a2c1 is the reflected component of the laser beam 108a2, and the laser beam 108a2c2 is the transmitted component of the laser beam 108a2, although the reverse may also be possible in another example. Accordingly, the laser beam 108a2c1 has an energy of T_{c}²Tₐ²Eᵢₙ², and the laser beam 108a2c2 has an energy of R_{c}²Tₐ²Eᵢₙ², as illustrated in FIG. 2.

Note that for any of the beam splitters 116a, 116b, 116c, a reflection coefficient R and a transmission coefficient is related as follows, assuming a substantially lossless beam splitting:

$${R}^{2} = 1 - {T}^{2} , \qquad Equation 1$$

where for example, R is Rₐ and T is Tₐ for the beam splitter 116a; R is R_{b} and T is T_{b} for the beam splitter 116b, and so on.

In an example, an output of a vapor cell (such as the laser beams 108a1 and/or 108a2) takes the form of: T₁=f_{SOI}+g_{INT}, where f_{SOI} (also referred to simply as f) is the contribution of the SOI 101 on the corresponding laser beam output by the vapor cell, and where g_{INT} (also referred to simply as g) is the contribution of the interfering signal 102 on the corresponding laser beam output by the vapor cell. Thus, here g_{INT} has a positive coefficient. In an example, the EOM 111 aims to generate a combined photodetector incident radiation of the form T′=f_{SOI}−g_{INT}, such that g_{INT} can later be cancelled at a summation node 140 described below.

In one embodiment, the various transmission and reflection coefficients in various beam splitters 116a, 116b, 116c can be determined by conservation of energy condition at the beam splitters (e.g., the combined energy going out of a beam splitter along corresponding two paths is the same as the energy going into the beam splitter) and generating a system of equations, as follows:

$$( 1 - {R}_{c}^{2} ) ( 1 - {R}_{a}^{2} ) {E}_{i n}^{2} = 2 {R}_{a}^{2} ( 1 - {R}_{b}^{2} ) {E}_{i n}^{2} , \qquad Equation 2 a$$

$${R}_{a}^{2} ( 1 - {R}_{b}^{2} ) {E}_{i n}^{2} = {R}_{a}^{2} {R}_{b}^{2} {E}_{i n}^{2} . \qquad Equation 2 b$$

Note that (1−R_{c}²) is T_{c}², and (1−Rₐ²) is Tₐ² (e.g., see equation 1 described above) Thus, (1−R_{c}²) (1−Rₐ²)Eᵢₙ² in equation 2a is T_{c}²Tₐ²Eᵢₙ², which is the laser beam 108a2c1. Similarly, Rₐ²(1−Rᵥ²)Eᵢₙ² in equation 2a is Rₐ²T_{b}²Eᵢₙ², which is the laser beam 108a1b2. Thus, in essence, equation 2a states that the energy of the laser beam 108a2c1 is twice the energy of the laser beam 108a1b2.

Also, Rₐ²(1−R_{b}²)Eᵢₙ² of equation 2b is Rₐ²T_{b}²Eᵢₙ², which is the laser beam 108a1b2. Finally, Rₐ²R_{b}²Eᵢₙ², is equation 2b is the laser beam 108a1b1. Thus, equation 2b states that the laser beam 108a1 is equally split in the laser beams 108a1b1 and 108a1b2 by the beam splitter 116b. Equation 2b can be simplified to show that

$${R}_{b}^{2} = \frac{1}{2} .$$

This provides a value of the reflection coefficient R_{b} at the beam splitter 116b. Consequently, the transmission coefficient T_{b} at the beam splitter 116b can be determined using equation 1 described above.

Different values of Rₐ and Rc can be selected to satisfy equation 2a. For example, if Rₐ²=¼, then from equation 2a, it can be deduced that

$${R}_{c}^{2} = \frac{1}{3} .$$

Thus, the following are an example set of values for the reflection coefficients at the beam splitters 116a, 116b, 116c:

$${R}_{b}^{2} = \frac{1}{2} , {R}_{a}^{2} = \frac{1}{4} , {R}_{c}^{2} = \frac{1}{3} . \qquad Equation 3 a$$

Note that as described above with respect to equation 1, Rₐ²+T₂²=1; R_{b}²+T_{b}²=1; R_{c}²+T_{c}²=1. Accordingly, example values of the transmission coefficients at the beam splitters 116a, 116b, 116c can be calculated using equations 1 and 3a as:

$${T}_{b}^{2} = \frac{1}{2} , {T}_{a}^{2} = \frac{3}{4} , {T}_{c}^{2} = \frac{2}{3} . \qquad Equation 3 b$$

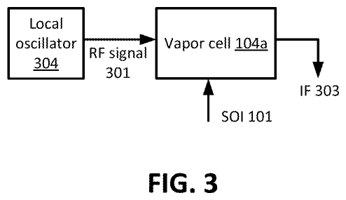

FIG. 3 illustrates a local oscillator 304 coupled to an example vapor cell 104a of the electromagnetic wave receiver system 100 of FIGS. 1 and 2, in accordance with an embodiment of the present disclosure. Applying an RF field of the SOI 101 that is on-resonance with the Rydberg transition acts as a local oscillator (LO), such as the LO 304 of FIG. 3, which causes the EIT effect in the Rydberg atoms to demodulate a second, co-polarized RF field of the SOI 101. The difference frequency, or an intermediate frequency (IF) 303, is detected by optically probing the Rydberg atoms within the vapor cell 104a. The phase of the IF signal 303 corresponds directly to the relative phase between the RF signal 301 from the LO 304 and the SOI 301. Similar description also applies to the vapor cell 104b.

Thus, a transmission from a vapor cell can be denoted as a function of the intermediate frequency IF (such as IF 303 from vapor cell 104a, see FIG. 3) and phase between the LO signal and the RF signal.

For example, a frequency of an intermediate frequency signal based on the SOI 101 is defined as Δω_{SOI}:=ω_{LO}−ω_{SOI}, where ω_{LO} is a frequency of the RF signal 301 from the LO 304, and ω_{SOI} is a frequency of the SOI 101. Similarly, a frequency of an intermediate frequency signal based on the interfering signal 102 is defined as Δω_{INT}:=ω_{LO}−ω_{INT}, and ω_{INT} is a frequency of the interfering signal 102.

Similarly, a phase of the intermediate frequency signal based on the SOI 101 is defined as Δω_{SOI}:=ϕ_{LO}−ϕ_{SOI}, where ϕ_{LO} and ϕ_{SOI} are the phases of the RF signal 301 and the SOI 101, respectively. Similarly, a phase of the intermediate frequency signal based on the interfering signal 102 is defined as Δϕ_{INT}:=ϕ_{LO}−ϕ_{INT} where ϕ_{INT} is a phase of the interfering signal 102.

Assume that the impinging probe fields on the photodetector 112a, 112b, 112c are denoted as E_{PD}_{₁}, E_{PD}_{₂}, and E_{PD}_{₃}, respectively, which are energy of the laser beams 108a1b1, 110, and 108a2c2, respectively. Then the impinging probe fields on the photodetector 112a, 112b, 112c are as follows:

$${E}_{{PD}_{1}} = {R}_{a} {R}_{b} {E}_{p r o b e} [ f ( Δ {ω}_{SOI} , {Δϕ}_{SOI} ) + g ( Δ {ω}_{INT} , {Δϕ}_{INT} ) ] \qquad Equation 4 a$$

$$Equation 4 b$$

$${E}_{{PD}_{2}} = {E}_{p r o b e} \{ {T}_{b} {R}_{a} [ f ( Δ {ω}_{SOI} , {Δϕ}_{SOI} ) + g ( Δ {ω}_{INT} , {Δϕ}_{INT} ) ] + {T}_{a} {T}_{c} [ g ( Δ {ω}_{INT} , {Δϕ}_{INT} ) ] {e}^{\frac{i π {V}_{1}}{2 {V}_{π}}} \}$$

$${E}_{{PD}_{3}} = {R}_{c} {T}_{a} {E}_{p r o b e} [ g ( Δ {ω}_{INT} , Δ {ϕ}_{INT} ) ] . \qquad Equation 4 c$$

Note that as described above, the vapor cell 104a is configured to be relatively more sensitive and responsive to both the SOI 101 and the interfering signal 102, e.g., compared to the vapor cell 104b. On the other hand, the vapor cell 104b is configured to be relatively more sensitive and responsive to the interfering signal 102, e.g., compared to the vapor cell 104a. Accordingly, in equation 4a, the photodetector 116a receives a component of the laser beam only from the vapor cell 104a that is sensitive to both the SOI 101 and the interfering signal 102, and hence, E_{PD}_{₁}, is a function of f(Δω_{SOI}, Δϕ_{SOI})+g(Δω_{INT}, Δϕ_{INT}), where f and g, as described before, are respective contributions of the SOI 101 and interfering signal 102 on the vapor cells.

Also note that while equations 2a and 2b were derived using conservation of energy condition at the beam splitters, equations 4a, 4b, 4c are derived using signal manipulations and/or modifications. For example, it may be useful to do signal level modifications, so as to take advantage of individual phases and perform interferometry, and achieve destructive interference. However, for all the above equations, conserving the energy through the beam splitters is used. In an example, Eᵢₙ used in equations 2a and 2b when using the conservation of energy condition at the beam splitters, and E_{probe} is used in equations 4a and 4b for field values.

On the other hand, in equation 4b, the photodetector 116b receives a combination of (i) the laser beam 108a1b2 from the vapor cell 104a that is sensitive to the SOI 101 and the interfering signal 102, and also (ii) the laser beam 108a2bc1p from the vapor cell 104b that is sensitive to the interfering signal 102. Accordingly, equation 4b has two components: (i) a first component that is a function of T_{b}R_{b} of the laser beam 108a1b2 and [f(Δω_{SOI}, Δϕ_{SOI})+g(Δω_{INT}, Δϕ_{INT})], and (ii) a second component that is a function of TₐT_{c} from the laser beam 108a2c1 and [g(Δω_{INT}, Δϕ_{INT})].

The term

$${e}^{\frac{i π {V}_{1}}{2 {V}_{π}}}$$

is expressive of the phase reversal by the EOM 111. For example, 2V_{π} is defined as a voltage that causes a 180 degree phase shift at the EOM 111, and V₁ is the voltage applied at the EOM 111. As described below, it is assumed that V₁=2V_{π}, such that the EOM 111 causes a 180 degree phase shift.

Finally, in equation 4c, the photodetector 116c receives a laser beam 108a2c2 from the vapor cell 104b that is sensitive to the interfering signal 102. Accordingly, in equation 4c, the E_{PD}_{₂} is based on R_{c}Tₐ of the laser beam 108a2c2 and g(Δω_{INT}, Δϕ_{INT}).

In an example, a voltage output of each photodetector (e.g., voltage of signal 120a of photodetector 112a) is substantially proportional (e.g., within a tolerance margin of at most 3%, or 2%) to a modulus of the impingent probe transmission (e.g., laser beam 108a1b1). In an example, a voltage output 120a of the photodetector 112a and a voltage output 120b of the photodetector 112b are summed at a voltage summer 140 of the electrical processing circuit 138. A difference between a voltage output 124 of the summer 140 and a voltage output 120c of the photodetector 112c is determined by a difference circuit 144 of the electrical processing circuit 138, which outputs a voltage signal Eₒᵤₜ 128. The output Eₒᵤₜ 128 can be expressed as:

$${E}_{out} = {\vert {E}_{{PD}_{1}} \vert}^{2} + {\vert {E}_{{PD}_{2}} \vert}^{2} - {\vert {E}_{{PD}_{3}} \vert}^{2} . \qquad Equation 5 a$$

By substituting various terms from equations 4a, 4b, and 4c in equation 5a, equation 5a can be rewritten as:

$$Equation 5 b$$

$${E}_{out} = A {\vert f \vert}^{2} + 2 ( A + cos ( \frac{π {V}_{1}}{2 {V}_{π}} ) B ) [ ℛe ( gf ) - 𝒥 𝓂 ( gf ) ] + 2 i sin ( \frac{π {V}_{1}}{2 {V}_{π}} ) B [ 𝒥 𝓂 ( g ) ℛe ( f ) - ℛe ( g ) 𝒥 𝓂 ( f ) ] + [ A + 2 cos ( \frac{π {V}_{1}}{2 {V}_{π}} ) B + C ] {\vert g \vert}^{2} .$$

In equation 5b, the terms A, B, and C are as follows:

$$A := {R}_{a}^{2} ( {R}_{b}^{2} + {T}_{b}^{2} ) , B := {T}_{b} {T}_{a} {T}_{c} {R}_{a} , C := {T}_{a}^{2} ( {T}_{c}^{2} - {R}_{c}^{2} ) . \qquad Equation 6 a$$

Substituent values from equations 3a and 3b in equation 6a, the values of A, B, and C in equation 6a, equation 6a can be rewritten as:

$$A = B = C = \frac{1}{4} . \qquad Equation 6 b$$

Furthermore, V₁=2V_{π}, as described above. Accordingly, substituting this value of V₁ and values from equation 6b into equation 5b, equation 5b can be rewritten as:

$${E}_{out} = \frac{1}{4} {\vert f \vert}^{2} . \qquad Equation 7$$

Thus, the final output Eₒᵤₜ 128 is based on f, which is the contribution of the SOI 101 only, and not the interfering signal 102. Thus, the effect of the interfering signal 102 is cancelled, or at least reduced, by the interferometer of the receiver 100, such that the output signal Eₒᵤₜ 128 is indicative only of, or at least primarily of, the SOI 101, as seen in equation 7. Thus, the interferometer 103 and the electrical processing circuit 138 are able to eliminate, or at least reduce, effects of the interfering signal 102 on the output signal Eₒᵤₜ 128. The output signal Eₒᵤₜ 128 is subsequently processed to estimate the SOI 101, in an example.

In an example, equation 7 is expected to be valid for exact valuation of the various control parameters that influence the receiver 100, such as the reflection and/or transmission coefficients of the various beam splitters. In practice, there may be some variations of the control parameters, e.g., based on a stochastic distribution with some width around the ideal or target values of these parameters. However, simulation results have shown that in spite of such minor variations of the control parameters (e.g., variations as high as 5% from their target values), an error in detection of the SOI 101 is within acceptable margin.

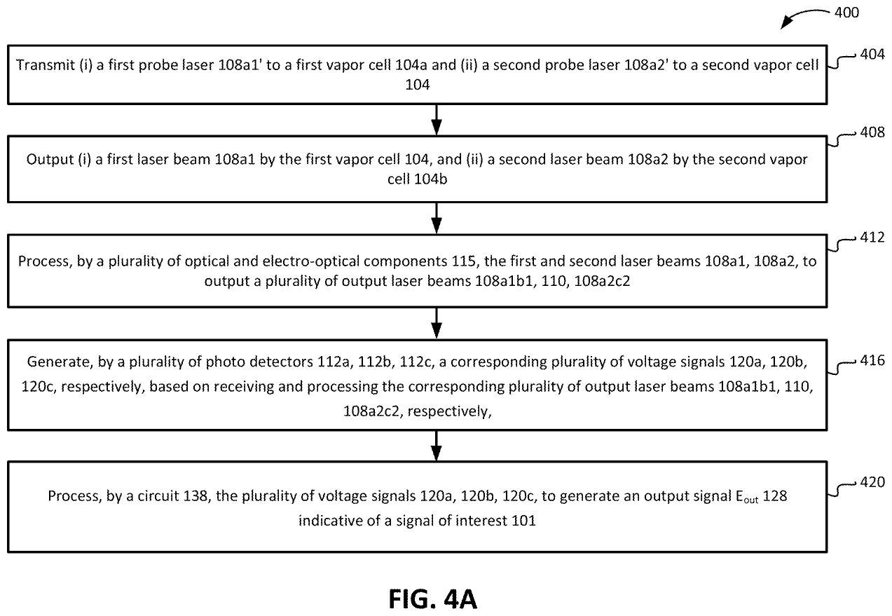

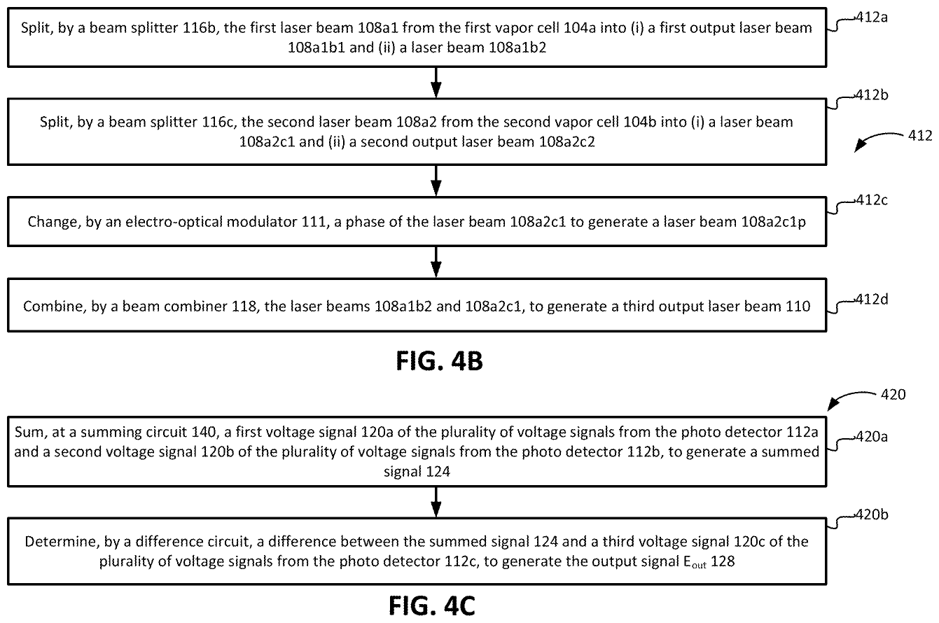

FIGS. 4A, 4B, and 4C, in combination, illustrate a flowchart depicting a method 400 of operating the electromagnetic wave receiver system 100 of FIGS. 1-3, in accordance with an embodiment of the present disclosure. Specifically, FIG. 4A illustrates the method 400 including processes 404, 408, 412, 416, and 420. FIG. 4B illustrates further details of the process 412 of FIG. 4A. FIG. 4C illustrates further details of the process 420 of FIG. 4A.

Referring to FIG. 4A, the method 400 comprises, at 404, transmitting (i) a first probe laser 108a1′ to a first vapor cell 104a and (ii) a second probe laser 108a2′ to a second vapor cell 104, as describe above with respect to FIGS. 1-3. For example, a beam splitter 116a splits an incoming probe laser beam 108, to generate the probe laser beams 108a1′ and 108a2′.

The method 400 proceeds from 404 to 408. At 408, the first vapor cell 104 outputs a first laser beam 108a1, and the second vapor cell 104b outputs a second laser beam 108a2. As described above, the laser beams 108a1 and 108a2 are indicative of the electrical field experienced by the first and second vapor cells, respectively.

The method 400 proceeds from 408 to 412. At 412, a plurality of optical and electro-optical components 115 processes the first and second laser beams 108a1, 108a2, to output a plurality of output laser beams 108a1b1, 110, 108a2c2, as described above with respect to FIGS. 1-3.

FIG. 4B describes the process 412 in further details. At 412a of FIG. 4B, a beam splitter 116b splits the first laser beam 108a1 from the first vapor cell 104a into (i) a first output laser beam 108a1b1 and (ii) a laser beam 108a1b2, as described above with respect to FIGS. 1-3. The first output laser beam 108a1b1 is received by the photodetector 112a.

At 412b of FIG. 4B, a beam splitter 116c splits the second laser beam 108a2 from the second vapor cell 104b into (i) a laser beam 108a2c1 and (ii) a second output laser beam 108a2c2. The second output laser beam 108a2c2 is received by the photodetector 112c.

At 412c of FIG. 4B, an electro-optical modulator 111 changes a phase of the laser beam 108a2c1, to generate a laser beam 108a2c1p. In an example, the EOM 111 provides a phase shift of substantially 180° (e.g., with a tolerance of at most 5°, or 3°, or 2°, or 1°), to generate the laser beam 108a2c1p. In an example, a phase shift provided by the EOM 111 can be controlled by a voltage V1 applied to the EOM 111.

At 412d, a beam combiner 118 combines the laser beams 108a1b2 and 108a2c1, to generate a third output laser beam 110. The third output laser beam 110 is received by the photodetector 112b. Subsequent to 412d, the method 400 proceeds from FIG. 4B to process 416 of FIG. 4A. Note that in an example, one or more of the processes 412a, 412b, 412c, 412d (such as the processes 412a and 412b) may be performed at least in part simultaneously.

At 416 of FIG. 4A, a plurality of photo detectors 112a, 112b, 112c generate a corresponding plurality of voltage signals 120a, 120b, 120c, respectively, based on receiving and processing the corresponding plurality of output laser beams 108a1b1, 110, 108a2c2, respectively, as described above with respect to FIGS. 1-3. In an example, a voltage output of each photodetector is substantially proportional (e.g., within a tolerance margin of at most 3%, or 2%) to a modulus of a corresponding impingent laser beam. For example, a voltage of signal 120a of photodetector 112a is substantially proportional to a modulus of the output laser beam 108a1b1.

The method 400 proceeds from 416 to 420. At 420, a circuit 138 processes the plurality of voltage signals 120a, 120b, 120c, to generate an output signal Eₒᵤₜ 128 indicative of a signal of interest 101. FIG. 4C describes the process 420 in further details. At 420a of FIG. 4C, a summing circuit 140 of the circuit 138 sums a first voltage signal 120a of the plurality of voltage signals from the photo detector 112a and a second voltage signal 120b of the plurality of voltage signals from the photo detector 112b, to generate a summed signal 124, as described above with respect to FIGS. 1-3. At 420b of FIG. 4C, a difference circuit 144 determines a difference between the summed signal 124 and a third voltage signal 120c of the plurality of voltage signals from the photo detector 112c, to generate the output signal Eₒᵤₜ 128 that is indicative of a signal of interest 101 (e.g., see equation 7 above).

Note that the processes in method 400 are shown in a particular order for ease of description. However, one or more of the processes may be performed in a different order or may not be performed at all (and thus be optional), in accordance with some embodiments. Numerous variations on method 400 and the techniques described herein will be apparent in light of this disclosure.

### FURTHER EXAMPLE EXAMPLES

The following examples pertain to further examples, from which numerous permutations and configurations will be apparent.

Example 1. A radio frequency (RF) receiver comprising: a first vapor cell and a second vapor cell; an interferometer configured to (i) process a first laser beam from the first vapor cell, and a second laser beam from the second vapor cell, and (ii) generate a plurality of voltage signals; and a circuit configured to process the plurality of voltage signals and generate an output signal indicative of a signal of interest.

Example 2. The RF receiver of example 1, wherein the interferometer comprises: a plurality of optical and electro-optical components configured to process the first and second laser beams, and produce a plurality of output laser beams; and a plurality of photodetectors, wherein each photodetector of the plurality of photodetectors is configured to receive a corresponding output laser beam of the plurality of output laser beams, and generate corresponding a voltage signal of the plurality of voltage signals.

Example 3. The RF receiver of any one of examples 1-2, wherein the interferometer comprises: a first beam splitter configured to receive the first laser beam from the first vapor cell, and split the first laser beam into a third laser beam and a fourth laser beam; and a second beam splitter configured to receive the second laser beam from the second vapor cell, and split the second laser beam into a fifth laser beam and a sixth laser beam.

Example 4. The RF receiver of example 3, wherein the interferometer comprises: a phase shifter configured to phase-shift the fifth laser beam to generate a seventh laser beam that has a phase in the range of 177 degrees to 183 degrees out-of-phase with a phase of the fifth laser beam.

Example 5. The RF receiver of example 4, wherein the phase shifter is an electro-optical modulator.

Example 6. The RF receiver of any one of examples 4-5, wherein the interferometer comprises: a beam combiner configured to receive the fourth laser beam and the seventh laser beam, and generate an eighth laser beam.

Example 7. The RF receiver of example 6, wherein the interferometer comprises: a first photodetector configured to receive the third laser beam, and generate a first voltage signal of the plurality of voltage signals; a second photodetector configured to receive the seventh laser beam, and generate a second voltage signal of the plurality of voltage signals; and a third photodetector configured to receive the sixth laser beam, and generate a third voltage signal of the plurality of voltage signals.

Example 8. The RF receiver of any one of examples 3-7, wherein: the first beam splitter is configured to split the first laser beam by (i) reflecting the first laser beam as one of the third or fourth laser beams, and (ii) transmitting the first laser beam as the other of the third or fourth laser beams; and a reflection coefficient of the first beam splitter is √(½), with a tolerance of at most 5%.

Example 9. The RF receiver of any one of examples 3-8, wherein: the second beam splitter is configured to split the second laser beam by (i) reflecting the second laser beam as one of the fifth or sixth laser beams, and (ii) transmitting the second laser beam as the other of the fifth or sixth laser beams; and a reflection coefficient of the second beam splitter is √(⅓), with a tolerance of at most 5%.

Example 10. The RF receiver of any one of examples 1-9, further comprising: an optical arrangement configured to (i) transmit a first probe laser beam to the first vapor cell, and (ii) transmit a second probe laser beam to the second vapor cell, wherein the optical arrangement comprises a beam splitter configured to (i) receive an incoming probe laser beam, (ii) reflect the incoming probe laser beam as one of the first probe laser beam and the second probe laser beam, and (ii) transmit the incoming probe laser beam as the other of the first probe laser beam and the second probe laser beam, wherein a reflection coefficient of the first beam splitter is ½, with a tolerance of at most 5%.

Example 11. The RF receiver of any one of examples 1-10, wherein the circuit comprises: a summation circuit configured to sum a first voltage signal of the plurality of voltage signals and a second voltage signal of the plurality of voltage signals, to generate a summed signal; and a difference circuit configured to difference the summed signal and a third voltage signal of the plurality of voltage signals, to generate the output signal.

Example 12. The RF receiver of any one of examples 1-11, wherein the first and second vapor cells includes an atomic medium comprising Rydberg atoms.

Example 13. The RF receiver of any one of examples 1-12, comprising: a first optical arrangement configured to (i) transmit a first probe laser beam to the first vapor cell, and (ii) transmit a second probe laser beam to the second vapor cell; and a second optical arrangement configured to (i) transmit a first pump laser beam to the first vapor cell and in a direction opposite to a direction of transmission of the first probe laser to the first vapor cell, and (ii) transmit a second pump laser beam to the second vapor cell and in a direction opposite to a direction of transmission of the second probe laser to the second vapor cell.

Example 14. A method comprising: transmitting, when a first vapor cell is exposed to a signal of interest and an interfering signal, a first probe laser to the first vapor cell; transmitting, when a second vapor cell is exposed to at least the interfering signal, a second probe laser to the second vapor cell; processing, by a plurality of optical and electro-optical components, the first and second laser beams, to output a plurality of output laser beams; generating, by a plurality of photo detectors, a corresponding plurality of voltage signals, respectively, based on receiving the corresponding plurality of output laser beams, respectively, such that each photo detector generates a corresponding voltage signal based on receiving a corresponding output laser beam; and processing, by a circuit, the plurality of voltage signals, to generate an output signal indicative of the signal of interest.

Example 15. The method of example 14, wherein processing the first and second laser beams to output the plurality of output laser beams comprises: splitting, by a first beam splitter, the first laser beam from the first vapor cell into (i) a third laser beam and (ii) a first output laser beam of the plurality of output laser beams; and splitting, by a second beam splitter, the second laser beam from the second vapor cell into (i) a fourth laser beam and (ii) a second output laser beam of the plurality of output laser beams.

Example 16. The method of example 15, wherein processing the first and second laser beams to output the plurality of output laser beams comprises: changing, by an electro-optical modulator, a phase of the fourth laser beam to generate a fifth laser beam; and combining, by a beam combiner, the third laser beam and the fifth laser beam, to generate a third output laser beam of the plurality of output laser beams.

Example 17. The method of any one of examples 14-16, wherein processing the plurality of voltage signals comprises: summing a first voltage signal of the plurality of voltage signals and a second voltage signal of the plurality of voltage signals, to generate a summed signal; and determining a difference between the summed signal and a third voltage signal of the plurality of voltage signals, to generate the output signal.

Example 18. A radio frequency (RF) receiver comprising: a first vapor cell and a second vapor cell, each of the first and second vapor cells comprising an atomic medium including Rydberg atoms; a combiner configured to combine a phase-shifted version of a light signal derived from the second vapor cell with a light signal derived from the first vapor cell, to generate a combined signal; a photodetector configured to receive the combined signal, and generate corresponding a first voltage signal; a summation circuit configured to sum the first voltage signal with a second voltage signal representative of light signal from the first vapor cell, to provide a summed signal; and a difference circuit configured to difference the summed signal and a third voltage signal representative of light signal from the second vapor cell, to generate an output signal.

Example 19. The RF receiver of example 18, wherein the photodetector is a first photodetector, the RF receiver further comprising: a second photodetector configured to generate the second voltage signal; and a third photodetector configured to generate the third voltage signal.

Example 20. The RF receiver of example 19, further comprising: a phase shifter having a phase shifter input and a phase shifter output, the phase shifter output coupled to a first input of the combiner; a first splitter configured to split light signal from the first vapor cell into (1) a first signal that is applied the second photodetector and (2) a second signal applied to a second input of the combiner; and a second splitter configured to split light signal from the second vapor cell into (1) a third signal that is applied to the phase shifter input and (2) a fourth signal that is applied to the third photodetector.

Numerous specific details have been set forth herein to provide a thorough understanding of the examples. It will be understood, however, that other examples may be practiced without these specific details, or otherwise with a different set of details. It will be further appreciated that the specific structural and functional details disclosed herein are representative of examples and are not necessarily intended to limit the scope of the present disclosure. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims. Furthermore, examples described herein may include other elements and components not specifically described, such as electrical connections, signal transmitters and receivers, processors, or other suitable components for operation of the antenna system 100.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and examples have been described herein. The features, aspects, and examples are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A radio frequency (RF) receiver comprising:
a first vapor cell and a second vapor cell;
an interferometer configured to (i) process a first laser beam from the first vapor cell, and a second laser beam from the second vapor cell, and (ii) generate a plurality of voltage signals; and
a circuit configured to process the plurality of voltage signals and generate an output signal indicative of a signal of interest.

2. The RF receiver of claim 1, wherein the interferometer comprises:
a plurality of optical and electro-optical components configured to process the first and second laser beams, and produce a plurality of output laser beams; and
a plurality of photodetectors, wherein each photodetector of the plurality of photodetectors is configured to receive a corresponding output laser beam of the plurality of output laser beams, and generate corresponding a voltage signal of the plurality of voltage signals.

3. The RF receiver of claim 1, wherein the interferometer comprises:
a first beam splitter configured to receive the first laser beam from the first vapor cell, and split the first laser beam into a third laser beam and a fourth laser beam; and
a second beam splitter configured to receive the second laser beam from the second vapor cell, and split the second laser beam into a fifth laser beam and a sixth laser beam.

4. The RF receiver of claim 3, wherein the interferometer comprises:
a phase shifter configured to phase-shift the fifth laser beam to generate a seventh laser beam that has a phase in the range of 177 degrees to 183 degrees out-of-phase with a phase of the fifth laser beam.

5. The RF receiver of claim 4, wherein the phase shifter is an electro-optical modulator.

6. The RF receiver of claim 4, wherein the interferometer comprises:
a beam combiner configured to receive the fourth laser beam and the seventh laser beam, and generate an eighth laser beam.

7. The RF receiver of claim 6, wherein the interferometer comprises:
a first photodetector configured to receive the third laser beam, and generate a first voltage signal of the plurality of voltage signals;
a second photodetector configured to receive the seventh laser beam, and generate a second voltage signal of the plurality of voltage signals; and
a third photodetector configured to receive the sixth laser beam, and generate a third voltage signal of the plurality of voltage signals.

8. The RF receiver of claim 3, wherein:
the first beam splitter is configured to split the first laser beam by (i) reflecting the first laser beam as one of the third or fourth laser beams, and (ii) transmitting the first laser beam as the other of the third or fourth laser beams; and
a reflection coefficient of the first beam splitter is
$$√ ( \frac{1}{2} ) ,$$
with a tolerance of at most 5%.

9. The RF receiver of claim 3, wherein:
the second beam splitter is configured to split the second laser beam by (i) reflecting the second laser beam as one of the fifth or sixth laser beams, and (ii) transmitting the second laser beam as the other of the fifth or sixth laser beams; and
a reflection coefficient of the second beam splitter is
$$√ ( \frac{1}{3} ) ,$$
with a tolerance of at most 5%.

10. The RF receiver of claim 1, further comprising: an optical arrangement configured to (i) transmit a first probe laser beam to the first vapor cell, and (ii) transmit a second probe laser beam to the second vapor cell, wherein the optical arrangement comprises a beam splitter configured to (i) receive an incoming probe laser beam, (ii) reflect the incoming probe laser beam as one of the first probe laser beam and the second probe laser beam, and (ii) transmit the incoming probe laser beam as the other of the first probe laser beam and the second probe laser beam, wherein a reflection coefficient of the first beam splitter is ½, with a tolerance of at most 5%.

11. The RF receiver of claim 1, wherein the circuit comprises:
a summation circuit configured to sum a first voltage signal of the plurality of voltage signals and a second voltage signal of the plurality of voltage signals, to generate a summed signal; and
a difference circuit configured to difference the summed signal and a third voltage signal of the plurality of voltage signals, to generate the output signal.

12. The RF receiver of claim 1, wherein the first and second vapor cells includes an atomic medium comprising Rydberg atoms.

13. The RF receiver of claim 1, comprising:
a first optical arrangement configured to (i) transmit a first probe laser beam to the first vapor cell, and (ii) transmit a second probe laser beam to the second vapor cell; and
a second optical arrangement configured to (i) transmit a first pump laser beam to the first vapor cell and in a direction opposite to a direction of transmission of the first probe laser to the first vapor cell, and (ii) transmit a second pump laser beam to the second vapor cell and in a direction opposite to a direction of transmission of the second probe laser to the second vapor cell.

14. A method comprising:
transmitting, when a first vapor cell is exposed to a signal of interest and an interfering signal, a first probe laser to the first vapor cell;
transmitting, when a second vapor cell is exposed to at least the interfering signal, a second probe laser to the second vapor cell;
outputting (i) a first laser beam by the first vapor cell, and (ii) a second laser beam by the second vapor cell;
processing, by a plurality of optical and electro-optical components, the first and second laser beams, to output a plurality of output laser beams;
generating, by a plurality of photo detectors, a corresponding plurality of voltage signals, respectively, based on receiving the corresponding plurality of output laser beams, respectively, such that each photo detector generates a corresponding voltage signal based on receiving a corresponding output laser beam; and
processing, by a circuit, the plurality of voltage signals, to generate an output signal indicative of the signal of interest.

15. The method of claim 14, wherein processing the first and second laser beams to output the plurality of output laser beams comprises:
splitting, by a first beam splitter, the first laser beam from the first vapor cell into (i) a third laser beam and (ii) a first output laser beam of the plurality of output laser beams; and
splitting, by a second beam splitter, the second laser beam from the second vapor cell into (i) a fourth laser beam and (ii) a second output laser beam of the plurality of output laser beams.

16. The method of claim 15, wherein processing the first and second laser beams to output the plurality of output laser beams comprises:
changing, by an electro-optical modulator, a phase of the fourth laser beam to generate a fifth laser beam; and
combining, by a beam combiner, the third laser beam and the fifth laser beam, to generate a third output laser beam of the plurality of output laser beams.

17. The method of claim 14, wherein processing the plurality of voltage signals comprises:
summing a first voltage signal of the plurality of voltage signals and a second voltage signal of the plurality of voltage signals, to generate a summed signal; and
determining a difference between the summed signal and a third voltage signal of the plurality of voltage signals, to generate the output signal.

18. A radio frequency (RF) receiver comprising:
a first vapor cell and a second vapor cell, each of the first and second vapor cells comprising an atomic medium including Rydberg atoms;
a combiner configured to combine a phase-shifted version of a light signal derived from the second vapor cell with a light signal derived from the first vapor cell, to generate a combined signal;
a photodetector configured to receive the combined signal, and generate corresponding a first voltage signal;
a summation circuit configured to sum the first voltage signal with a second voltage signal representative of light signal from the first vapor cell, to provide a summed signal; and
a difference circuit configured to difference the summed signal and a third voltage signal representative of light signal from the second vapor cell, to generate an output signal.

19. The RF receiver of claim 18, wherein the photodetector is a first photodetector, the RF receiver further comprising:
a second photodetector configured to generate the second voltage signal; and
a third photodetector configured to generate the third voltage signal.

20. The RF receiver of claim 19, further comprising:
a phase shifter having a phase shifter input and a phase shifter output, the phase shifter output coupled to a first input of the combiner;
a first splitter configured to split light signal from the first vapor cell into (1) a first signal that is applied the second photodetector and (2) a second signal applied to a second input of the combiner; and
a second splitter configured to split light signal from the second vapor cell into (1) a third signal that is applied to the phase shifter input and (2) a fourth signal that is applied to the third photodetector.
